(19) United States
(12) Patent Application Publication
(10) Pub. No.: US 2013/0224452 A1
(43) Pub. Date: Aug. 29, 2013

(54) METAL NANOPARTICLE-GRAPHENE COMPOSITES AND METHODS FOR THEIR PREPARATION AND USE

(71) Applicants: Sundara Ramaprabhu, Chennai (IN); Tessy Theres Baby, Chennai (IN)

(72) Inventors: Sundara Ramaprabhu, Chennai (IN); Tessy Theres Baby, Chennai (IN)

(73) Assignee: Indian Institute of Technology Madras, Tamil Nadu (IN)

(21) Appl. No.: 13/407,337

(22) Filed: Feb. 28, 2012

(51) Int. Cl. B05D 5/12; B32B 15/04; B32B 9/00; C23C 14/08; C23C 14/18

(52) U.S. Cl. 428/209; 427/600; 427/113; 427/529; 427/531; 428/408; 428/195.1

(57) ABSTRACT

Methods of forming a metal nanoparticle-graphene composite are provided. The methods include providing a functionalized hydrogen exfoliated wrinkled graphene (f-HEG) substrate and dispersing metal nanoparticles on a first major surface of the f-HEG substrate to form the metal nanoparticle-graphene composite.

### BACKGROUND

A variety of cathode materials are known and are in use in electronic applications such as flat panel displays, electron microscopes and X-ray sources. The electron emission in such materials is by application of external energy. Some devices use field emission that is a quantum mechanical tunneling phenomena. In operation, electrons are emitted from a surface of the material into a vacuum in response to an applied electric field.

Typically, the external electric field applied to a field emission device is of the order of about 10⁹ V/m. In order to reduce this high external field, materials with customized properties are being used. For example, carbon nanomaterials are used in certain field emission applications owing to properties such as relatively higher surface area, high mechanical strength and electrical conductivity. The sharp ends/edges of carbon nanotubes (CNT) are responsible for the field emission. In certain other applications, graphene is used for field emission devices. However, in planar graphene, the emission is substantially from edges that may require a substantial high electric field to be applied to the field emission device.

### SUMMARY

Briefly, in accordance with one aspect, methods of forming a metal nanoparticle-graphene composite are provided. The methods can include providing a functionalized hydrogen exfoliated wrinkled graphene (f-HEG) substrate and dispersing metal nanoparticles on a first major surface of the f-HEG substrate to form the metal nanoparticle-graphene composite.

In accordance with another aspect, metal nanoparticle-graphene composites are provided. The metal nanoparticle-graphene composites can include a functionalized hydrogen exfoliated wrinkled graphene (f-HEG) substrate and a plurality of metal nanoparticles dispersed on a first major surface of the f-HEG substrate.

In accordance with another aspect, field emission devices are provided. The field emission devices can include a plurality of zinc oxide (ZnO) nanoparticles uniformly dispersed on a functionalized hydrogen exfoliated wrinkled graphene (f-HEG) substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 illustrates materials and/or compositions used/formed at different stages of forming a metal nanoparticle-graphene composite.

FIG. 2 is an example transmission electron microscopy (TEM) image of hydrogen exfoliated wrinkled graphene (HEG) formed by exfoliating graphite oxide.

FIG. 3 is an example field emission scanning electron microscopy (FESEM) image of HEG placed on a carbon cloth.

FIG. 4 is an example FESEM image of f-HEG substrate with tin oxide (SnO₂) nanoparticles dispersed on the substrate.

FIG. 5 is an example TEM image of the f-HEG substrate with the tin oxide nanoparticles.

FIG. 6 is an example FESEM image of the f-HEG substrate with zinc oxide (ZnO) nanoparticles dispersed on the substrate.

FIG. 7 is an example TEM image of the f-HEG substrate with zinc oxide (ZnO) nanoparticles dispersed on the substrate.

FIG. 8 is an example FESEM image of the ZnO-HEG nanocomposite coated on a carbon cloth.

FIG. 9 illustrates XRD patterns of SnO₂—HEG and ZnO-HEG composites.

FIG. 10 is Raman spectra of SnO₂—HEG and ZnO-HEG composites.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

It will also be understood that any compound, material or substance which is expressly or implicitly disclosed in the specification and/or recited in a claim as belonging to a group or structurally, compositionally and/or functionally related compounds, materials or substances, includes individual representatives of the group and all combinations thereof.

Example embodiments are generally directed to composites comprising graphene and metal nanoparticles and use of such composites in field emission devices. The field emission devices using the metal nanoparticle-graphene composites may be used in a variety of electronic systems such as flat panel displays, electron microscopes and X-ray sources, among others.

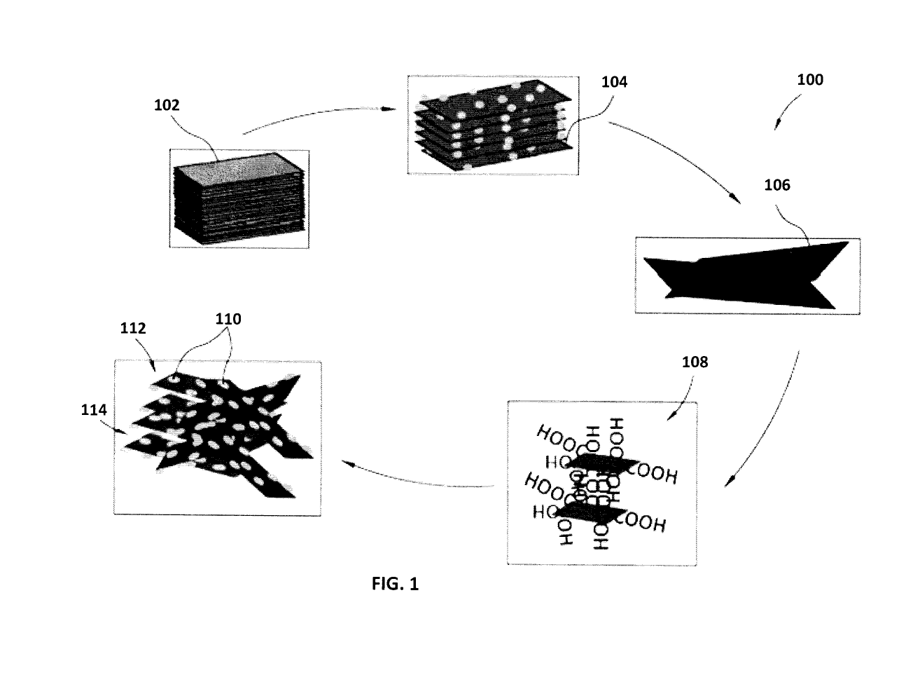

Referring now to FIG. 1, materials and/or compositions 100 used/formed at different stages of forming a metal nanoparticle-graphene composite are illustrated. In the illustrated embodiment, graphite 102 is oxidized to form graphite oxide 104. In one embodiment, graphite oxide 104 is formed using Hummer's method as is known in the art. Moreover, graphite oxide 104 is exfoliated in presence of hydrogen to form hydrogen exfoliated wrinkled graphene (HEG) 106. In one example embodiment, graphite oxide may include basal planes occupied by —OH groups. These —OH groups may be at least partially removed through the exposure of hydrogen and the application of heat in an exothermic reaction. The exothermic reaction may supply sufficient energy to disrupt the basal planes of graphite oxide resulting in exfoliation and/or reduction of graphite oxide into HEG.

It should be noted that the HEG 106 includes residual hydrogen atoms from processing of the graphite oxide 104 in hydrogen atmosphere. The residual hydrogen atoms facilitate reduction in turn-on field and threshold field of the HEG 106. In particular, the enhancement of electric current at low electric field is due to the charge distribution on carbon and hydrogen atoms and the resulting surface dipoles. At low electric fields, a large dipole moment is created between hydrogen and carbon atoms and the direction of the field is such that it assists in the extraction of electrons from graphene thereby reducing the work function.

In the illustrated embodiment, the HEG is further sonicated in presence of an acid medium to form a functionalized hydrogen exfoliated wrinkled graphene (f-HEG) substrate 108. The acid medium may include sulphuric acid (H₂SO₄), nitric acid (HNO₃), or both sulphuric acid and nitric acid. The f-HEG substrate 108 includes a plurality of foldings that define electron emission sites. The charge accumulation at the edges of the substrate and at the foldings of graphene provides a low-energy barrier and enhanced electron emission.

Moreover, metal nanoparticles 110 are dispersed on a first major surface 112 of the f-HEG substrate 108 to form a metal nanoparticle-graphene composite 114. The metal nanoparticles 110 may include platinum (Pt), palladium (Pd), silver (Ag), gold (Au), nickel (Ni), titanium (Ti), tin (Sn), ruthenium (Ru) or combinations thereof.

In another example embodiment, the metal nanoparticles 110 include metal oxide nanoparticles. Examples of metal nanoparticles 110 include, but are not limited to, zinc oxide (ZnO), tin oxide (SnO₂), ruthenium oxide (RuO₂), cobalt oxide (Co₃O₄), copper oxide (CuO), titanium dioxide (TiO₂) and vanadium pentoxide (V₂O₅). In some embodiments the metal nanoparticles 110 cover between about 10% to about 30% of the total surface area of the f-HEG substrate 108. In one example embodiment the metal nanoparticles 110 cover about 20% of the total surface area of the f-HEG substrate 108. The metal nanoparticles 110 may be dispersed on the f-HEG substrate 108 using deposition techniques such as a chemical reduction technique, a sol-gel technique and sputtering. However, other suitable deposition techniques may be employed.

The metal nanoparticles 110 dispersed on the f-HEG substrate 108 reduce the work function of the substrate 108 and substantially increase the surface roughness of the substrate 108 thereby enhancing the field emission properties of the metal nanoparticle-graphene composite 114.

The metal nanoparticle-graphene composite 114 may be incorporated into a field emission device owing to the enhanced field emission properties of the composite. In particular, the foldings of the f-HEG substrate 108 provide additional field emission sites that provide a low-energy barrier and enhanced electron emission. In addition, the metal nanoparticles 110 dispersed on the f-HEG substrate 108 enhance the field emission properties of the composite by reducing the work function of the f-HEG substrate 108.

The example metal nanoparticles-graphene composites described above may be used as cathode materials in a variety of electronic application such as flat panel displays, X-ray sources and field emission electron microscopes. Other applications including use of large-area field emission devices such as described above include microwave generation, space-vehicle neutralization and multiple e-beam lithography. In certain embodiments, the metal nanoparticles-graphene composites may be used as field effect transistors.

### EXAMPLES

The present invention will be described below in further detail with examples and comparative examples thereof, but it is noted that the present invention is by no means intended to be limited to these examples.

### Example 1

### Formation of Graphite Oxide from Graphite

Graphite oxide was formed using Hummer's method. Here, about 2 grams (g) of graphite was added to about 46 milliliters (ml) of concentrated sulphuric acid (H₂SO₄), such as by hand or machine, while stirring continuously in an ice bath. Further, about 1 g of sodium nitrate (NaNO₃) and about 6 g of potassium permanganate (KMNO₄) were added gradually to the ice bath. The ice bath was subsequently removed and the suspension was allowed to come to room temperature. At this point, about 92 ml of water was added to the above mixture and was allowed to settle for about 15 minutes. The above mixture was then diluted to achieve a volume of about 280 ml using warm water. Distilled or de-ionized or doubly distilled water was added, such as by hand or machine, to the mixture.

Following this, about 3% of hydrogen peroxide (H₂O₂) was added to the above mixture until the solution turned to a bright yellow color. The suspension was then filtered with a filter to produce a filter cake. Moreover, the filter cake was washed with warm water repeatedly. The residue was further diluted using water and the resulting suspension was centrifuged. The final product was dried under vacuum to form graphite oxide and stored in vacuum desiccators.

### Example 2

### Formation of HEG from Graphite Oxide

Graphite oxide was placed in a quartz boat that was placed inside a tubular furnace. The furnace was sealed at both ends with end couplings having provision for allowing gas into the furnace. Then, the furnace was flushed with an inert gas such as Argon (Ar) for about 15 minutes and the temperature of the furnace was raised to about 200° C. Further, pure hydrogen (H₂) gas was allowed within the furnace at that temperature. The exfoliation occurred within about 1 minute to form the HEG.

### Example 3

### Formation of a Field Emitter Film

To form the field emitter film, about 10 mg of HEG was dispersed in about 1 ml of 0.5% Nafion solution by ultrasonication. This dispersion was later spin coated on a flexible carbon cloth at a speed of about 500 rpm in a first stage and at a speed of about 2000 rpm in a second stage. The film was further heated under vacuum for about 12 hours to remove solvent.

### Example 4

### Configuration of a Test Set-Up Used for Determining Field Emission Properties of the Field Emitter Film of Example 3

The field emission properties of a spin coated film were determined by loading it in a setup, which included a stainless steel cathode and a gold coated copper anode. The surface morphology and defects of the HEG field emitter film were studied using field emission scanning electron microscopy (FESEM) and transmission electron microscopy (TEM).

### Example 5

### Surface Morphology Patterns and Results of the HEG Obtained Using the Test Set-Up of Example 4

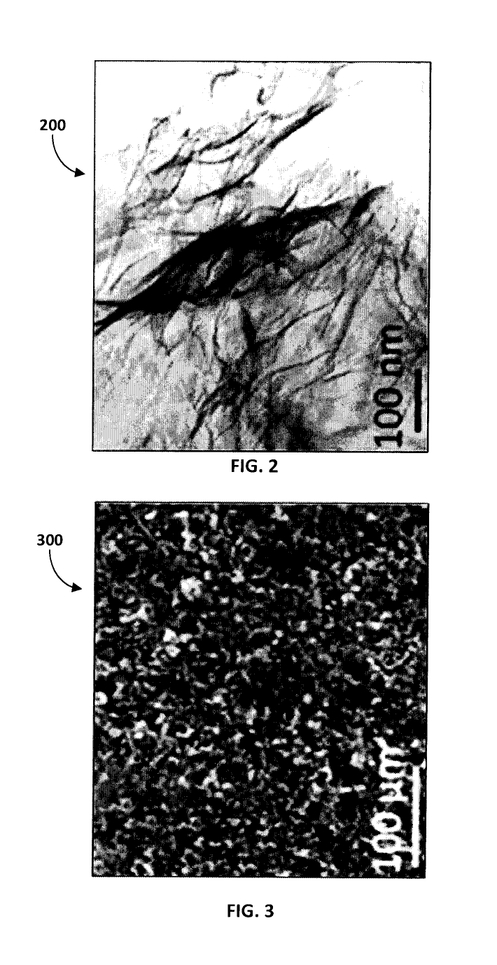

FIG. 2 illustrates a TEM image 200 of HEG. Moreover, FIG. 3 illustrates a FESM image 300 of HEG on a carbon cloth of Example 3. As can be seen, nearly uniform coating of HEG on carbon cloth is visible in the image 300. Moreover, the images 200 and 300 show a plurality of foldings on the HEG substrate, which functioned as field emission sites that provided a low-energy barrier and enhanced electron emission.

The turn-on field and the threshold fields were measured for the HEG. The turn-on field for a current density of about 10 μA/cm² and threshold field for a current density of about 0.2 mA/cm² were measured to be about 1.18 V/μm and 1.43 V/μm respectively. Further, the field enhancement factor (β) was calculated from a Fowler-Nordheim (F-N) plot and was estimated to be about 4907. It should be noted that foldings and wrinkles on the graphene facilitated enhanced performance of HEG as a field emitter. In particular, the foldings on the graphene substantially lowered electron affinity that provided a low-energy barrier and enhanced electron emission.

The electrical conductivity of HEG was measured using a four probe method and was estimated at around 1.6×10³ S/m. The large surface area of HEG was about 442.9 m²/g that further enhanced field emission properties. Moreover, presence of residual hydrogen atoms in the HEG also reduced the turn-on voltage and threshold voltage of HEG. In particular, the hydrogen atoms adsorbed on the surface and edges of HEG aggregated to form localized states near the Fermi level, which is responsible for the emission.

### Example 6

### Dispersion of Metal Nanoparticles on a f-HEG Substrate to Form a Metal Nanoparticle-Graphene Composite

The as-synthesized HEG was functionalized in 3:1 H₂SO₄:HNO₃ acid medium and metal nanoparticles were dispersed on the functionalized HEG. Zinc oxide (ZnO) nanoparticles were dispersed on the f-HEG using a sol-gel technique. Here, about 1 g zinc acetate was dissolved in about 20 ml anhydrous ethanol, and then the f-HEG was added to it along with about 0.05 g citric acid. The additions were accompanied by stirring and sonication.

Subsequently, a solution composed of about 650 mg oxalic acid and about 20 ml anhydrous ethanol was slowly added to the zinc acetate/HEG solution while stirring. The temperature during this process was maintained at about 60° C. and the sample was dried at a temperature of about 70° C. The calcination of the final product was done at a temperature of about 450° C. for about 2 hours under presence of nitrogen for a proper phase formation of ZnO in ZnO/HEG composite. The ZnO particles dispersed on the HEG reduced the work function of HEG effectively and increased the surface roughness, thereby enhancing the field emission properties of the composite.

In another example, tin oxide (SnO₂) nanoparticles were dispersed on the f-HEG substrate by using a chemical reduction technique. Here, about 200 mg of tin (II) chloride was added to about 20 ml of distilled (DI) water and was sonicated for about 5 minutes. This was subsequently added to about 200 mg of f-HEG dispersed in about 20 ml of DI water, which was sonicated for about 30 minutes. The above mixture was stirred for about 24 hours and tin was reduced from 5 nCl₂ using a reducing solution, which was a mixture of about 1M NaBH₄ and about 0.1 M NaOH. Once the reaction was over, the solution was washed with DI water and filtered using a cellulose membrane filter. The material obtained was further dried at a temperature of about 70° C. under vacuum for about 6 hours and the final product was annealed at a temperature of about 350° C. for about 2 hours.

### Example 7

### Surface Morphology Patterns and Results for the Metal-Nanoparticles-Graphene Composites

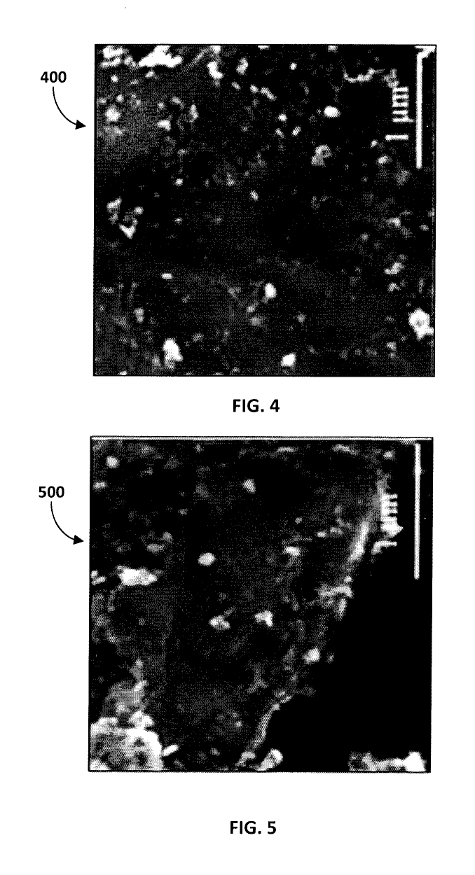

FIG. 4 is an example FESEM image 400 of f-HEG substrate 108 with tin oxide (SnO₂) nanoparticles dispersed on the substrate. Further, FIG. 5 is an example TEM image 500 of the f-HEG substrate with the tin oxide nanoparticles. The distribution of the tin oxide nanoparticles on the surface of the f-HEG substrate is clearly seen in the images 400 and 500.

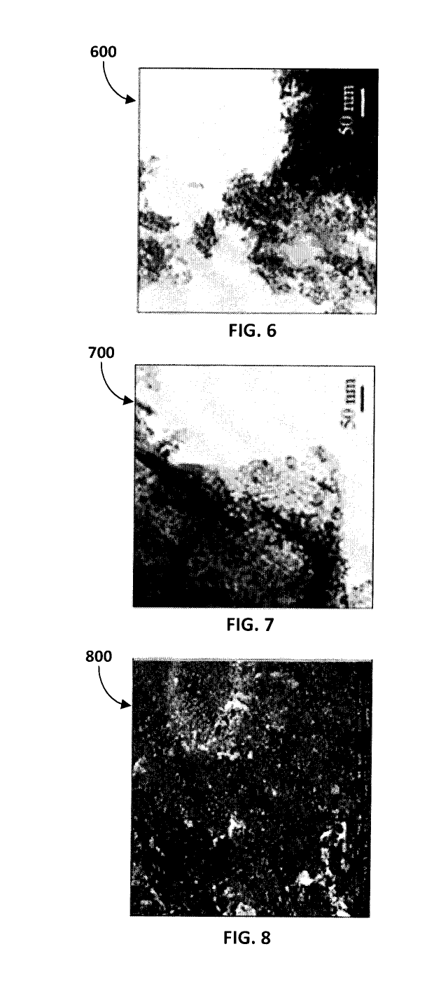

FIG. 6 is an example FESEM image 600 of the f-HEG substrate 108 with zinc oxide (ZnO) nanoparticles dispersed on the substrate 108. FIG. 7 is an example TEM image 700 of the f-HEG substrate 108 with zinc oxide (ZnO) nanoparticles dispersed on the substrate 108. FIG. 8 is an example FESEM image of the ZnO-HEG nanocomposite coated on a carbon cloth. The surface morphology and particle distribution on graphene are visible in the images 600, 700 and 800. It should be noted that the foldings on graphene substrate can be seen in the TEM image 700 of the ZnO-HEG composite.

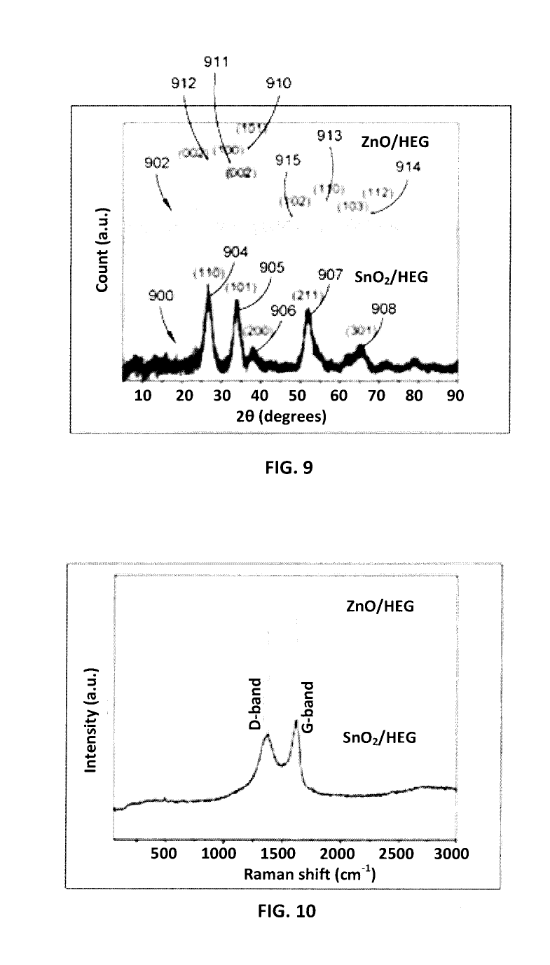

FIG. 9 illustrates XRD patterns 900 and 902 of SnO₂—HEG and ZnO-HEG composites described above with reference to example 6. Here, the broad peak of HEG at about 25 degrees was merged with the highest intensity peak 904 of SnO₂ at about 26.6 degrees. The SnO₂ peak 904 at about 26.6 degrees corresponded to a (110) plane. The other peaks 905, 906, 907 and 908 at about 33.8 degrees, 37.9 degrees, 51.7 degrees and 65.7 degrees corresponded to (101), (200), (211) and (301) planes of SnO2, respectively. The peak positions were compared with Joint Committee on Powder Diffraction Standards (JCPDS) and indexed accordingly. Further, the crystalline size of tetragonal SnO₂ was estimated using Scherrer's equation and was found to be about 6 nm.

In the case of the ZnO-HEG composite, along with the HEG peak at 25°, hexagonal peaks of ZnO were also present. The peaks generally represented by reference numerals 910, 911, 912, 913, 914 and 915 at 36.2 degrees, 31.7 degrees, 34.3 degrees, 56.5 degrees, 62.7 degrees, 67.8 degrees and 47.4 degrees corresponded to (101), (100), (002), (110), (103), (112) and (102) planes of ZnO nanoparticles, respectively. Here, the crystalline size calculated using the Scherrer's equation was about 9 nm.

FIG. 10 is Raman spectra 1000 of SnO₂—HEG and ZnO-HEG composites. Here, the Raman shift in a wave number range of about 1350 cm⁻¹ to about 1380 cm⁻¹ was referred to as a D-band and was due to the presence of defects, disorder and sp³ hybridized carbon atoms present in the sample. The peak that existed in the wave number range of about 1570 cm⁻¹ to about 1620 cm⁻¹ is the characteristic peak of most of the carbonaceous samples. This peak was referred to as the G-band and was due to the sp² hybridized carbon atoms. In the case of metal nanoparticle-graphene composites, there is a shift in the G-band position as compared to pure HEG, which was due to the interaction of metal oxide nanoparticles with graphene.

### Example 8

### Comparative Results for Turn-on Field and Field Enhancement Factors for Metal Nanoparticles-Graphene Composite Described Above Relative to Existing Materials Used for Field Emission Devices

Table 1 shows turn-on fields for current density of about 10 μA/cm² and field enhancement factors for the metal nanoparticle-graphene composite described above and other materials.

TABLE 1

| | | | Field enhance- |
|---|---|---|---|
| Material | Turn-on field | | ment factor |
| HEG | 1.18 | V μm⁻¹ | 4907 |
| CuO nanowire film | 3.5-4.5 | V μm⁻¹ | 1570 |
| Straw like CuO | 2.8-3 | V μm⁻¹ | 1100 |
| Carbon nanotubes with nano- | 3.1-4 | V μm⁻¹ | — |
| sized RuO₂ particles | | | |
| Planar Graphene | 12.1 | V | 3519 |
| CuO-HEG composite | 1.1 | V μm⁻¹ | 7099 |
| RuO₂-HEG composite | 0.91 | V μm⁻¹ | 7621 |
| SnO₂-HEG composite | 0.93 | V μm⁻¹ | 6367 |
| ZnO nanowires grown on | 2 | V μm⁻¹ | 3834 |
| reduced graphene/PDMS | | | |
| Graphene-polyaniline | 3.91 V/μm | | 7012 |
| | (1 μA/cm2) | | |
| ZnO-graphene sheet | 1.3 V/μm | | 15000 |
| | (1 μA/cm2) | | |
| ZnO-HEG composite | 0.88 | V μm⁻¹ | 6535 |

As can be seen, the turn-on field obtained for the ZnO-HEG composite was about 0.88 V μm⁻¹ that is much lower as compared to other existing materials. Moreover, field emission devices using such composites have good stability and repeatability. The low threshold field and good field enhancement factor value compared to planar graphene was achieved by the wrinkled morphology of HEG and the presence of residual hydrogen atoms.

The defects/foldings on the graphene sheet also lowered electron affinity that provided a low-energy barrier and enhanced electron emission. The turn-on field and threshold field were further reduced with metal nanoparticles dispersed on the HEG substrate. Moreover, the graphene-based composites are substantially cost effective compared to other carbon nanostructures. Since, the maximum current density obtained for the ZnO-HEG composite is also higher than most of the above mentioned field emitters, the proposed field emitter has wide area of application in the electronic industry.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.).

It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc.

As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method of forming a metal nanoparticle-graphene composite, the method comprising:
providing a functionalized hydrogen exfoliated wrinkled graphene (f-HEG) substrate; and
dispersing metal nanoparticles on a first major surface of the f-HEG substrate to form the metal nanoparticle-graphene composite.

2. The method of claim 1, wherein the metal nanoparticles comprise platinum (Pt), palladium (Pd), silver (Ag), gold (Au), nickel (Ni), titanium (Ti), tin (Sn), ruthenium (Ru), or combinations thereof.

3. The method of claim 1, wherein the metal nanoparticles comprise metal oxide nanoparticles.

4. The method of claim 3, wherein the metal oxide nanoparticles comprise zinc oxide (ZnO), tin oxide (SnO₂), ruthenium oxide (RuO₂), cobalt oxide (Co₃O₄), copper oxide (CuO), titanium dioxide (TiO₂), vanadium pentoxide (V₂O₅), or combinations thereof.

5. The method of claim 1, wherein providing the f-HEG substrate comprises:
oxidizing graphite to form graphite oxide;
exfoliating graphite oxide in presence of hydrogen (H₂) to form hydrogen exfoliated wrinkled graphene (HEG); and
sonicating HEG in presence of an acid medium to form the f-HEG substrate.

6. The method of claim 5, wherein the acid medium comprises sulphuric acid (H₂SO₄), nitric acid (HNO₃), or both sulphuric acid and nitric acid.

7. The method of claim 1, wherein the metal nanoparticles are dispersed on the f-HEG substrate using a chemical reduction technique.

8. The method of claim 1, wherein the metal nanoparticles are dispersed on the f-HEG substrate using a sol-gel technique.

9. The method of claim 1, wherein the metal nanoparticles are dispersed on the f-HEG substrate using sputtering.

10. A metal nanoparticle-graphene composite comprising:
a functionalized hydrogen exfoliated wrinkled graphene (f-HEG) substrate; and
a plurality of metal nanoparticles dispersed on a first major surface of the f-HEG substrate.

11. The metal nanoparticle-graphene composite of claim 10, wherein the f-HEG substrate is formed by exfoliating graphite oxide in presence of hydrogen (H₂) to form HEG, and subsequently sonicating the HEG in presence of an acid medium to form the f-HEG substrate.

12. The metal nanoparticle-graphene composite of claim 11, wherein the f-HEG substrate comprises residual hydrogen atoms.

13. The metal nanoparticle-graphene composite of claim 10, wherein the f-HEG substrate comprises a plurality of foldings on the first major surface of the substrate.

14. The metal nanoparticle-graphene composite of claim 10, wherein the metal nanoparticles comprise platinum (Pt), palladium (Pd), silver (Ag), gold (Au), nickel (Ni), titanium (Ti), tin (Sn), ruthenium (Ru), zinc oxide (ZnO), tin oxide (SnO₂), ruthenium oxide (RuO₂), cobalt oxide (Co₃O₄), copper oxide (CuO), titanium dioxide (TiO₂), vanadium pentoxide (V₂O₅), or combinations thereof.

15. The metal nanoparticle-graphene composite of claim 10, wherein the metal nanoparticles cover about 20% of the total surface area of the f-HEG substrate.

16. The metal nanoparticle-graphene composite of claim 11, wherein the composite is incorporated into a field emission device.

17. A field emission device comprising:
a plurality of zinc oxide (ZnO) nanoparticles uniformly dispersed on a functionalized hydrogen exfoliated wrinkled graphene (f-HEG) substrate.

18. The field emission device of claim 17, wherein the f-HEG substrate comprises a plurality of foldings defining electron emission sites of the field emission device.

19. The field emission device of claim 17, wherein the f-HEG substrate is formed by exfoliating graphite oxide in presence of hydrogen (H₂) to form HEG and subsequently sonicating the HEG to form the f-HEG substrate.

20. The field emission device of claim 19, wherein the f-HEG substrate comprises residual hydrogen atoms configured to substantially reduce a turn-on field of the field emission device.

21. The field emission device of claim 17, wherein the ZnO nanoparticles are configured to reduce a work function of the f-HEG substrate.

22. The field emission device of claim 17, wherein a turn-on field of the device is about 0.88 V μm⁻¹.
